(19) United States
(12) Patent Application Publication
(10) Pub. No.: US 2024/0091919 A1
(43) Pub. Date: Mar. 21, 2024

(54) FASTENING TOOL HAVING HOME POSITION SENSING SYSTEM

(71) Applicant: Black & Decker, Inc., New Britain, CT (US)

(72) Inventors: Joel Ngui, Selangor (MY); Luke Moloznick, Baltimore, MD (US)

(21) Appl. No.: 18/384,398

(22) Filed: Oct. 27, 2023

Related U.S. Application Data
(63) Continuation of application No. PCT/US2022/024929, filed on Apr. 14, 2022.
(60) Provisional application No. 63/174,950, filed on Apr. 14, 2021.

(51) Int. Cl. B25C 1/04; B25C 1/06

(52) U.S. Cl. CPC B25C 1/047; B25C 1/06

(57) ABSTRACT

A fastening tool using Hall sensor technology as a contactless solution to home position sensing of a drive shaft. In this manner, an omnipolar switch Hall effect sensor PCB assembly can be placed in a fastening tool housing or on a driving mechanism of the tool to detect a magnet that is attached to a drive shaft. The drive shaft is attached to an eccentric member that can control the height or position of a compression piston. On the piston return cycle, the piston must stop within a predetermined range from bottom dead center in order to be in the home position. Through the connection with the eccentric member, the drive shaft carrying the magnet also returns to its home position. In the drive shaft home position, the magnet is within the Hall effect sensor sensing zone. As a result, the Hall effect sensor can detect the magnetic flux and send a corresponding signal to the controller.

### CROSS-REFERENCE TO RELATED APPLICATIONS

The present application claims priority to U.S. Provisional Patent Application Ser. No. 63/174,950 entitled “Fastening Tool Having Home Position Sensing System”, filed Apr. 14, 2021 and is a continuation of international application PCT/US2022/024929, filed on Apr. 14, 2022. The entirety of the above applications are incorporated herein by reference.

### BACKGROUND OF THE INVENTION

### Field of the Invention

The present invention relates, in general, to the field of power tools. In particular, the present invention relates to a fastening or driving tool, such as a nailer and more particularly to improvements in such tools for sensing the position of components therein. In particular, the present invention relates to a fastening tool having a home position sensing mechanism to sense the position of the drive shaft.

### Description of the Related Art

Different types of fastening tools are known including portable pneumatically actuated devices, electrically actuated devices, hammer actuated devices, manual actuated devices, etc. Fastening tools, such as power nailers have become relatively common place in the construction industry. Battery-powered nailers are popular in the market.

A common characteristic of all these types of fastening tools is the provision of a drive track, a fastener driving element mounted in the drive track and a magazine assembly for receiving a supply of fasteners in stick formation and feeding successive leading fasteners in the stick laterally into the drive track to be driven outwardly thereof by the fastener driving element and a transmission system for driving a drive shaft that drives operation of the fastening tool. The drive shaft and other components need to start from a home position to actuate a successful and complete drive cycle or sequence. However, mechanical switches, such as micro-limit switches in home position detection mechanisms, can be unreliable due to a lack of mechanical robustness. The unreliability of such switches causes the position detection mechanism to fail in a multitude of ways such as by overtravel, physical deformation of components, degradation of internal switching mechanisms caused by cycle fatigue, and electrical overload. These aforementioned failures can cause no signal or a faulty signal to be sent to the control module. Accordingly, there is a need in the art for a fastening tool that has repeatable performance when the system is properly reset at the home position, between drive cycles. The system must be able to accurately and reliably transmit an electrical signal to the control module when the drive shaft is in its home position.

### SUMMARY OF THE INVENTION

In an embodiment, a fastening tool includes a housing; a nosepiece assembly connected to the housing and including a fastener drive track having a drive axis; a magazine assembly for feeding a number of fasteners successively along a fastener channel to the fastener drive track of the nosepiece assembly; a driver member provided in the housing and configured for movement along the drive axis to drive a lead fastener into a workpiece; a motor disposed within the housing and configured to drive the driver member along the drive axis; a power source providing power to the motor; and a controller in the tool housing configured to control a supply of power from the power source to the motor and initiate a drive cycle. A drive assembly has a drive shaft rotatably connected to the driver member. A sensor target is disposed on one end of the drive shaft and having a characteristic that changes in response to the change in position. A sensor is configured to sense the characteristic of the sensor target and send a signal to the controller in response to the characteristic. When the controller receives the signal from the sensor, the controller starts the next drive cycle.

In an embodiment, the switch operation includes changing a signal between ON and OFF.

In an embodiment, the tool housing includes a trigger assembly that activates a drive cycle that causes the compressor piston to travel between at least two positions, and the controller in the tool housing connects the trigger assembly to the drive assembly.

In an embodiment, the housing defines a handle portion, and wherein the trigger assembly is connected to the tool housing, adjacent the handle portion.

In an embodiment, the sensor target is a magnet.

In an embodiment, the sensor is one of a Hall effect sensor and an omnipolar switch Hall effect sensor.

In an embodiment, the sensor target is mounted on one of the drive shaft and the housing.

In an embodiment, the sensor target is mounted on the other of the drive shaft and the housing.

In an embodiment, a compression piston is disposed within a first compression chamber in the housing, an eccentric member is rotatable by the drive shaft and slidably connected to the compression piston, and the eccentric member controls a position of a compression piston member within the first compression chamber.

Features and benefits of the present invention are described, and will be apparent from, the accompanying drawings and the detailed description below.

### BRIEF DESCRIPTION OF THE DRAWINGS

The numerous advantages of the present invention may be better understood by those skilled in the art by reference to the accompanying Figures. In the drawings, like reference numerals designate corresponding parts throughout the several views.

FIG. 1 is a side view of an exemplary fastening tool constructed in accordance with the teachings of the present disclosure with a portion of the housing removed to show the trigger assembly, battery pack mount and drive motor assembly;

FIG. 2 is a cross-sectional view of the tool of FIG. 1 with the housing removed to show the compression chambers;

FIG. 3 illustrates the home position sensing system of the tool of FIG. 1;

FIG. 4 illustrates the home position sensing system of the tool of FIG. 1;

FIG. 5 illustrates the home position sensing system of the tool of FIG. 1 showing the drive shaft attached to an eccentric;

FIG. 6 illustrates the home position sensing system drive cycle of the tool of FIG. 1 showing the drive shaft in rotation;

FIG. 7 illustrates the home position sensing system drive cycle of the tool of FIG. 1 with the piston at top dead center;

FIG. 8 illustrates the home position sensing system drive cycle of the tool of FIG. 1 with the piston returning to bottom dead center; and

FIG. 9 illustrates the home position sensing system drive cycle of the tool of FIG. 1 with the piston at bottom dead center.

### DETAILED DESCRIPTION OF THE INVENTION

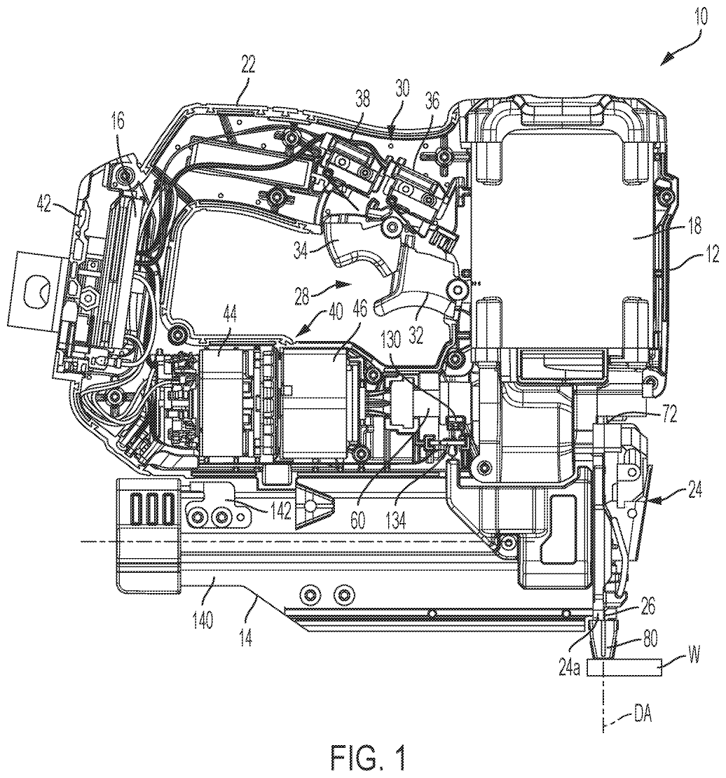

FIG. 1 illustrates a fastening tool 10 according to an embodiment of the invention.

According to several aspects, the fastening tool 10 is a battery powered nailer, however the fastening tool can be any type of portable tool including a pneumatic nailer. The fastening tool 10 includes a housing 12 containing a compression cylinder 18, a nosepiece assembly 24 extending forward of and fixed to the housing 12, a magazine assembly 14, a control module or controller 16, a trigger assembly 28 and a drive motor assembly 40. The magazine assembly 14 is connected to a nose portion 24a of the nosepiece assembly 24. The nosepiece assembly 24 is coupled to the drive motor assembly 40 and defines a fastener drive track 26 through which fasteners, such as nails, are driven. The fastening tool 10 is designed to drive one or more fasteners into a workpiece W.

Fasteners can be temporarily contained in the magazine assembly 14, which can be connected to the nosepiece assembly 24. The magazine assembly 14 can include a fixed magazine portion 140 and a movable magazine portion (not shown) slidably disposed on the fixed magazine portion. The fixed 140 and movable magazine portions are held together by a magazine latch 142. The magazine assembly 14 is constructed and arranged to feed successive leading fasteners from a supply of fasteners inserted between the fixed and movable magazine portions 140, along a feed track or fastener channel and into the drive track 26 of the nosepiece assembly 24. In an embodiment, the supply of fasteners can be collated fasteners. The supply of fasteners is urged toward the drive track 26 by at least one magazine pusher or plurality of pushers that are slidably disposed in grooves in the magazine assembly 14. The magazine pusher or pushers travels along a magazine pusher path or fastener channel. The magazine pusher or pushers can be biased towards the drive track 26 by a spring or plurality of springs (not shown) that push respective pushers toward the drive track 26. The magazine pusher or pushers engages the last fastener in the supply of fasteners to thereby feed individual fasteners from the magazine assembly 14 to the nosepiece assembly 24.

The fasteners can be nails, staples, brads, clips or any such suitable fastener that can be driven into the workpiece W.

In an embodiment, a no-mar tip 80 can be attached to the nose portion 24a of the nosepiece assembly 24 to prevent marring of the workpiece when the nose is placed against the workpiece for driving a fastener.

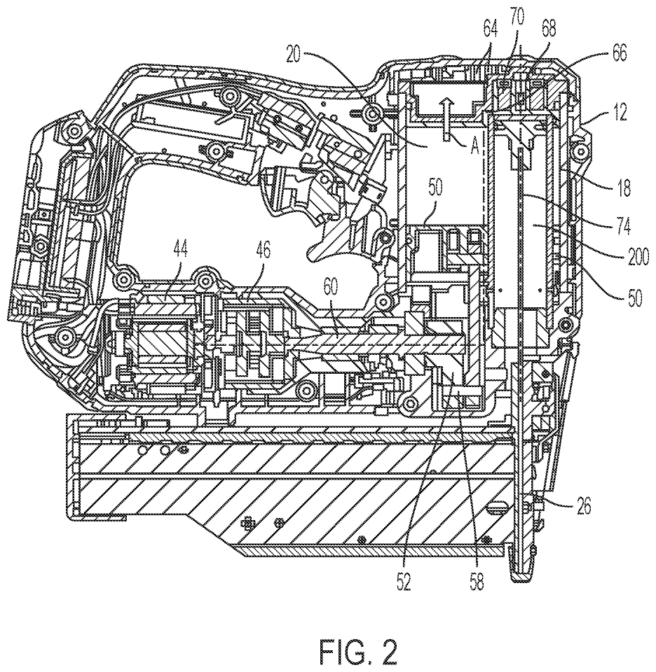

As illustrated in FIGS. 1 and 2, a handle portion of the fastening tool 10 extends substantially perpendicularly from the housing 12. The handle 22 is configured to be received by a user's hand, thereby making the fastening tool 10 portable. Additional portability can be achieved by constructing the housing 12 from a lightweight yet durable material, such as plastic or magnesium.

The trigger assembly 28 is pivotably connected to the handle 22. The trigger assembly 28 serves as an actuation device or actuator for the fastening tool 10, and is constructed and arranged to actuate a trigger switch assembly 30. The trigger assembly 28 may be coupled to the housing 12 and is configured to receive an input from the user, typically by way of the user's finger(s), that may be employed in conjunction with the trigger switch assembly 30 to generate a trigger signal that may be employed, in part, to initiate the drive cycle of the fastening tool 10 to drive the fastener into the workpiece W.

The trigger assembly 28 includes a primary trigger 32 and a secondary trigger 34. The trigger switch assembly 30 includes a primary switch 36 that is actuated by the primary trigger 32 and a secondary switch 38 that is actuated by the secondary trigger 34. The primary and secondary triggers 32, 34 are pivotably mounted to the handle 22 so as to be grasped by the user's finger(s) when the user holds the tool by hand along the handle.

In operation, the secondary trigger 34 is actuated or pulled first to activate the secondary switch 38 which sends a signal to the controller 16 to power the fastening tool. Upon detecting the actuation of the secondary trigger 34, the controller 16 can instruct the power source to deliver power to the fastening tool. Powering of the fastening tool includes the activation of any lights and sensors for checking for fasteners in the magazine assembly 14. After the secondary trigger 34 is pulled, the primary trigger 32 is actuated or pulled to activate the primary switch 36. The primary switch 36 sends a signal to the controller 16 to activate the drive motor assembly 40. The primary and secondary switches 36, 38 may be disposed within the handle portion 22 of the fastening tool 10.

As used herein, the term controller can refer to an application specific integrated circuit (ASIC), an electronic circuit, a processor (shared, dedicated, or group) and memory that executes one or more software or firmware programs, a combinational logic circuit, other suitable components and/or one or more suitable combinations thereof that provide the described functionality.

The drive motor assembly 40 of the fastening tool 10 extends from the nosepiece assembly 24 and includes additional components necessary for activating the fastening tool and driving a fastener. In an embodiment, the drive motor assembly 40 may extend substantially perpendicularly within the housing 12. Alternatively, the drive motor assembly 40 may extend substantially perpendicularly within a separate drive assembly housing. The drive motor assembly 40 can be disposed between the power source and the nosepiece assembly 24. The drive motor assembly 40 includes a motor 44, a transmission gear system 46 and a drive shaft 60. The power source may supply electrical energy, to operate the motor 44 of the drive motor assembly 40 and the trigger assembly 28. In an embodiment, the power source is a battery pack (not shown). The controller 16 is configured to control a supply of power from the power source to the motor 44 to initiate the drive cycle upon receipt of the trigger signal from the primary trigger 32.

In an embodiment, the battery pack can be removably coupled to a battery pack mount 42 at the distal end of the handle 22 and distal end of the drive motor assembly 40. For example, the battery pack can be slidably mounted onto and slidably released from the battery pack mount 42.

The drive motor assembly operatively connects the motor 44 with the drive shaft 60. As such, upon activation of the motor 44 and transmission gear system 46, the drive shaft 60 rotates. The drive shaft 60 drives the operation of the compression cylinder 18. The compression cylinder 18 controls the operation of a driver member 72 that drives a fastener out of the fastening tool. The drive shaft 60 transmits power from the motor 44 to the compression piston 50. The presence and/or absence of compressed air in the compression cylinder 18 directs the driver member 72 to translate within the drive track 26. The presence or absence of compressed air is controlled by a compression piston 50 disposed in the compression cylinder 18.

The compression piston 50 is moveable within the compression cylinder 18 by a reciprocating connecting rod 54. The drive shaft 60 is connected to the compression piston 50 through an operatively connected eccentric member 52 and connecting rod 54. The connecting rod 54 is connected to the eccentric member 52 by a pin 58. The eccentric member 52 converts the rotary motion of the drive shaft 60 into linear reciprocating motion of the connecting rod 54 to drive the compression piston 50.

As illustrated in FIGS. 1 and 2, the housing 12 includes the compression cylinder 18 in which a gas, such as air is compressed. In particular, the compression cylinder 18 contains a first compression chamber 20 and a second compression chamber 200. The first compression chamber 20 and second compression chamber 200 are substantially defined within the compression cylinder 18. The first compression chamber 20 generates compressed air in the tool. Air intake vents 48 are arranged on a portion of the first compression chamber 20 to receive air. The air intake vents 48 draw in air from the housing 12 into the compression chamber 20 when the piston 50 moves from bottom dead center to top dead center. The compressed air generated in the first compression chamber 20 moves in the direction of arrow A (FIG. 2) and is channeled through apertures in a valve insert 66 to the second compression chamber or drive cylinder 200 in which the reciprocating driver member 72 is disposed. The driver member 72 is configured to drive a leading fastener along a drive axis DA out of the fastener drive track 26 and into the workpiece W. The driver member 72 can have a driver blade 74 that impacts the fastener and drives the fastener into the workpiece W. Each drive cycle includes a drive stroke in which the driver member 72 moves from a home position at the top of the drive cylinder 200 toward the nosepiece assembly 24 along the drive axis DA and drives the leading fastener into the workpiece W, and a return stroke in which the driver member 72 is returned to its initial or home position so that it is ready for the next drive stroke.

In order for the fastening tool to be ready for a drive cycle and execute successful drive and return strokes, the drive shaft 60 needs to be returned to its home position. In this regard, Hall effect sensor technology is a contactless solution to home position sensing of components in the fastening tool. In an embodiment, Hall effect sensor technology is a contactless solution to home position sensing of the drive shaft 60. In this manner, an omnipolar switch Hall effect sensor printed circuit board (PCB) assembly 134 can be placed in a fastening tool housing 12. The omnipolar switch responds to either the north or south pole of a magnet. The circuit board 134 can include a Hall effect sensor 120 that detects a sensor target such as a magnet 130 that is attached to the drive shaft 60.

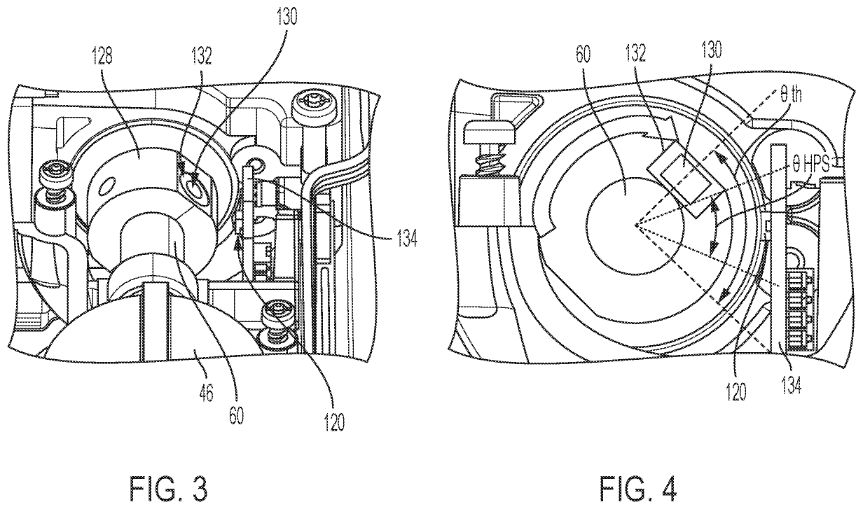

As shown in FIGS. 3 and 4, the Hall effect sensor 120 detects or senses at least one of the magnetic orientation and the magnetic flux of the magnet 130. Since the magnet 130 is coupled for rotation with the drive shaft 60, the change in position of the magnet as the drive shaft rotates, results in a change in magnetic orientation or magnetic flux. The Hall effect sensor 120 is configured to send a signal to the controller 16 indicative of at least one of the magnetic orientation and the magnetic flux of the magnet 130. If the magnetic orientation and/or the magnetic flux is detected, the controller 16 instructs the fastening tool motor 44 to begin the next drive cycle.

In an embodiment of the present invention, the magnet 130 can be mounted in or on a magnet carrier 128 located at an end of the drive shaft 60 opposite to the drive motor assembly 40. The magnet 130 can be insert-molded into a ring or sleeve 132 within the magnet carrier 128 that is pressed onto or press-fit into the drive shaft 60. In an embodiment, the magnet 130 can be disposed within a plastic sleeve. In an alternative embodiment, the magnet 130 can be disposed within a metal sleeve, such as a steel sleeve.

The Hall effect sensor 120 is remote from the drive shaft 60 and coupled to the circuit board 134 on an inner surface of the housing 12. As illustrated in FIGS. 3 and 4 the magnet 130 is arranged on the drive shaft 60 to rotate through a sensing zone θₜₕ as the drive shaft 60 rotates. As the magnet rotates through the sensing zone, the magnet is sensed by the remote Hall effect sensor 120. As the magnet rotates through the sensing zone θ_{HPS} (θ home position sensing), the Hall effect sensor 120 senses that the drive shaft 60 is in the home position.

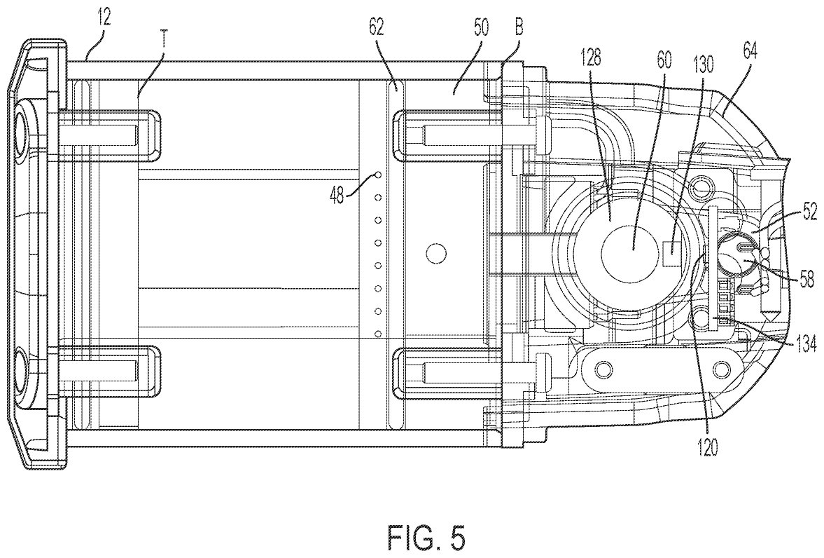

In an embodiment, as shown in FIG. 5, the Hall effect sensor 120 can be positioned adjacent to the magnet carrier 128. The Hall effect sensor is a contactless switch such that interfacing with the magnet 130 causes the switch to send a signal to the controller 16. It will be appreciated, however, that any type of non-contact sensor, such as an Eddy-current sensor, or a contact-type sensor could be employed.

Also as shown in FIG. 5, the drive shaft 60 is attached to an eccentric member. The eccentric 52 member is, in turn, attached to a compression piston 50 thereby coupling the compression piston to the drive shaft 60. The eccentric member 52 can control the height and/or movement of the compression piston 50. As shown in FIGS. 5 to 9, a full drive and return cycle has the compression piston 50 start from the home position near bottom dead center B of the cycle, move upward to top dead center T, and stop or return to the home position near bottom dead center B. FIG. 5 shows that the compression piston 50 is located at its bottom dead center position B. In this position, the magnet 130 is in line with the Hall effect sensor 120 and the drive shaft 60 can be sensed at the home position.

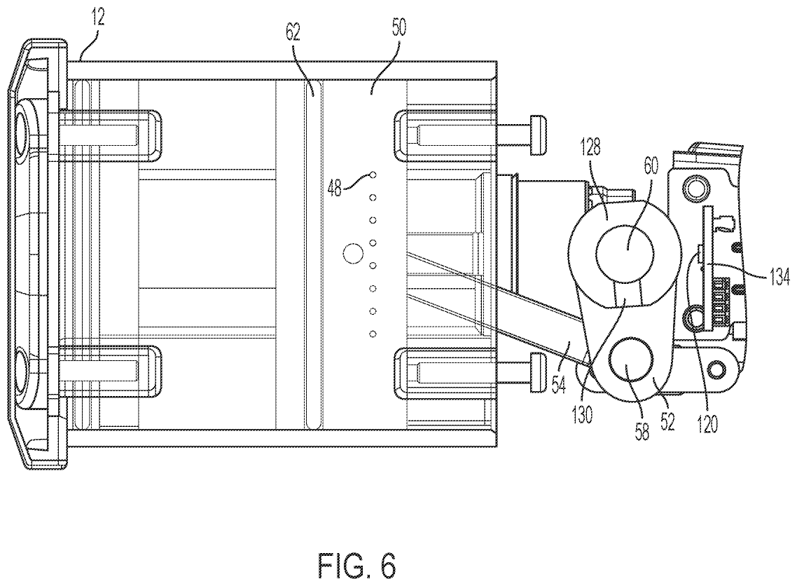

FIG. 6 illustrates the compression piston 50 located at a position away from the bottom dead center position and moving toward the top dead center position T. As shown, the magnet 130 has moved out of the sensing zone θₜₕ of the Hall effect sensor 120. The Hall effect sensor 120 can therefore send a signal to the controller 16 that the drive shaft 60 is not in the home position. In this illustrated position, the compression piston 50 compresses air between the piston head, or top of the piston 50 and the valve insert 66 in the first compression chamber 20.

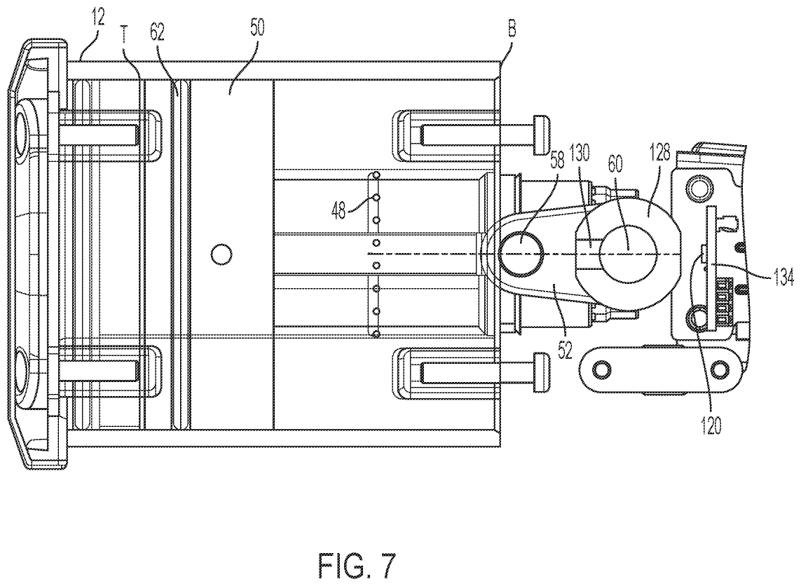

FIG. 7 illustrates the compression piston 50 at top dead center T. In this position, the compression piston 50 has pushed air toward the apertures 64 in the valve insert 66 connecting the first compression chamber 20 with the second compression chamber or drive cylinder 200. In this position, the magnet 130 is located 180° away from the Hall effect sensor 120. The Hall effect sensor 120 can therefore send a signal to the controller 16 that the drive shaft 60 is not in the home position. Such a signal can be, for example, a digital signal of LOW.

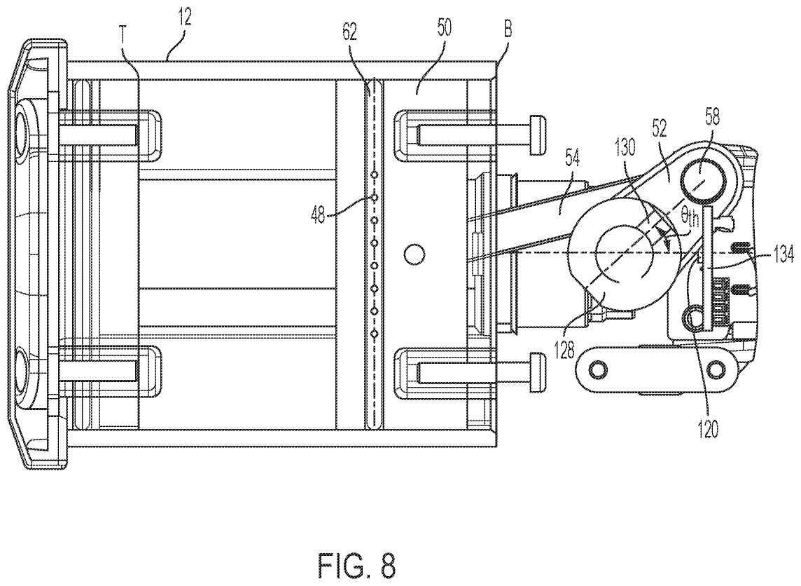

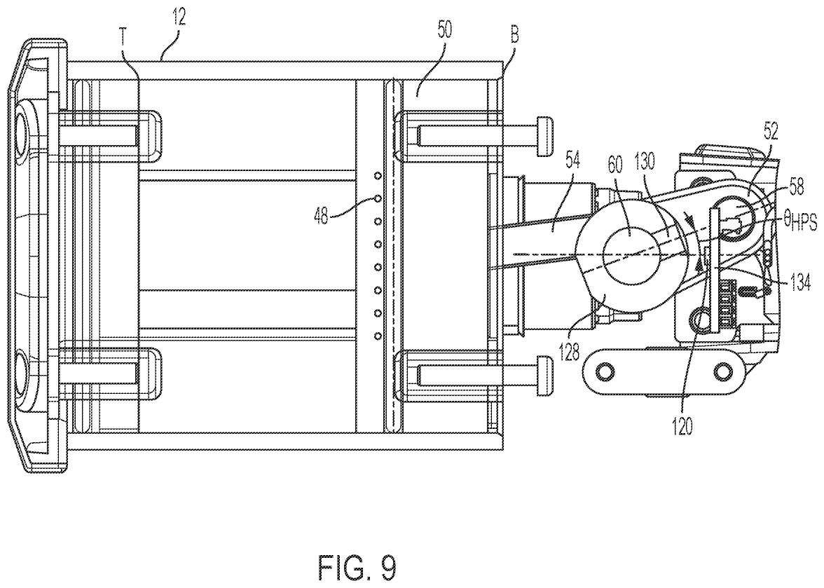

FIG. 8 illustrates the piston return cycle in which the compression piston 50 must stop within a predetermined distance, from its bottom dead center position B, in order to be sensed as being in the home position. In an embodiment, the distance from bottom dead center can be measured from the top surface of the compression piston 50. The home position of the compression piston 50 is the position where the piston is in the optimum position to start the next drive cycle. The home position for the compression piston 50 can be an at-rest state. In an embodiment, the home position of the compression piston 50 is the bottom dead center position of the piston within the compression chamber 20, as shown in FIGS. 5 and 9.

In its home position, as shown in FIGS. 5 and 9, the drive shaft 60 can be in the optimum position to start the next drive cycle. The home position for the drive shaft 60 can be an at-rest state. Hall effect sensor 120 can detect magnetic flux or shift in polarity and send a signal change to the controller indicating that the drive shaft 60 is in the home position. In an embodiment, the Hall effect sensor detects the magnet and changes a signal, such as a digital signal from HIGH to LOW. If the Hall effect sensor does not detect the magnet or the magnet is out of range, such as outside of the sensing zone θ_{HPS}, the sensor sends a digital signal of LOW to the controller 16, and the controller will issue an instruction to brake the motor 44. The home position of the drive shaft 60 is the position where the magnet is within the angular range defined by θₜₕ. In an embodiment, the home position of the drive shaft 60 is within the angular range defined by θ_{HPS}. In a further embodiment the home position of the drive shaft is a position in which the magnet is in line with or at a 180° angle, through the axis of the drive shaft, from the Hall effect sensor.

When both the compression piston 50 and the drive shaft 60 are in their respective home positions, the Hall effect sensor can send a signal or signal change to the controller 16 instructing the motor to start the next drive cycle. If one or both of the compression piston and the drive shaft 60 are not in their respective home positions, the Hall effect sensor does not send a signal, at which point the controller 16 does not start the motor 44 or next drive cycle.

When the drive shaft 60 rotates out of the home position, the compression piston 50 moves past air intake vents 48 in the compression chamber 20 (FIGS. 6 and 7) and the pressure between the top of the piston (piston head) and the top or rear of the compression chamber increases. The resulting pressurized air passes through the apertures 64 (FIG. 1) in a valve insert 66 located between the first compression chamber 20 and an inner end of the compression cylinder 18. The pressurized air that passes through the apertures 64 is channeled to the drive cylinder 200, where the pressurized air applies a force to the top of the driver member 72. The top of the driver member 72 includes a metallic member 68 that is attracted to a driver blade magnet 70 at the top of the drive cylinder 200. The driver member is magnetically held within the drive cylinder 200 in a home position.

Release of the pressure in the first compression chamber 20 occurs when the pressure on the driver member 72 increases sufficiently to overcome the magnetic force of the driver blade magnet 70 on the metallic portion 68 of the driver member. The release of the pressure is used to actuate the drive assembly. In particular, the release of the pressure is used to move the driver member 72 from an at-rest state to a fastener driving state to drive the fastener.

In an exemplary embodiment, the home position of the compression piston 50, is where the compression piston is close to and/or at its bottom dead center position. The home position of the compression piston can be within a predetermined range of its bottom dead center position. In an embodiment, the predetermined range can be for example, approximately 0 mm to 3.5 mm before or beyond its bottom dead center position. Also, in the piston home position, the O-ring seal 62 does not block the compression cylinder vents 48. Therefore, the compression piston 50 does not create a sealed pressure environment within the compression cylinder 18. As a result, fresh or new air can enter the compression chamber 20. See FIGS. 5 and 9. In a sealed pressure environment within the compression cylinder 18, however, the compression chamber 20 does not vent and fresh or new air cannot enter. As a result, the compression chamber 20 cannot generate the required air pressure necessary to overcome the magnetic force on the driver member 72 to move the driver member from an at-rest-state to a fastener driving state.

In an embodiment of the present invention, the Hall effect sensor 120 detects magnetic flux from the magnet 130 attached to the drive shaft 60 such that the Hall effect sensor output signal switches from first state to a second state when the drive shaft is in the angular range defined by θₜₕ or θ_{HPS}. For example, when the Hall effect sensor sends a signal indicating that it is ON, the drive shaft 60 is in the home position; and when the Hall effect sensor sends a signal indicating that it is OFF, the drive shaft is not in the home position. Alternatively, the Hall effect sensor can send a digital signal, HIGH or LOW to the controller 16 based on the presence of the magnet 130 in proximity. This precision is achieved by controlling the alignment of the magnet 130 during assembly of the magnet carrier 128 onto the drive shaft 60 relative to the mating of the eccentric 52 and drive shaft.

In an embodiment, as shown in FIG. 8, the compression piston 50 stops near bottom dead center when the O-ring seal 62 on the compression piston is near the air intake vents 48 and the bottom of the compression chamber 20. In an embodiment, as shown in FIG. 9, the compression piston 50 stops at or past bottom dead center when the O-ring seal 62 on the compression piston is between the air intake vents 48 and the bottom of the compression chamber 20, to allow the compression chamber 18 to bleed compressed air through the air intake vents. In an exemplary embodiment, the compression piston 50 stops when the piston is past bottom dead center. This piston position corresponds to the angular range in which the drive shaft 60 has returned to its home position, such as at the end of a full drive and return cycle. The home position of the drive shaft 60 is the position where a fixed point on the drive shaft is located within an angular range θ_{HPS} sensed by the Hall effect sensor. In the home position, the drive shaft 60 is in an at-rest state and in position to begin the next drive cycle.

In an embodiment, the drive shaft 60 must stop within the defined sensing range of the Hall effect sensor 120 so that the magnet 130 can be sensed. In addition, when the compression piston 50, which is actuated by the drive shaft 60, is in a position away from the air intake vents 48, the vents 48 are open to the atmosphere. The open or unobstructed vents allow for air to enter into the compression chamber 20 so that the air can be compressed during the next drive cycle. As long as θₜₕ>θ_{HPS}, namely, the detection of the magnet on the drive shaft 60 occurs within the angular range that the compression piston 50 is allowed to vent to atmosphere, the drive shaft will always stop in the correct position.

θ_{HPS} can be determined by: (1) the distance and alignment of the Hall effect sensor 120 relative to the center of the shaft; (2) the strength of the magnet 130; and (3) θ_{HPS} being a percentage of θₜₕ. as shown in FIG. 5. In an embodiment, the percentage can be 0 or 10% or 20%. For example, θₜₕ can be and angle of about 80° and, θ_{HPS} is about 30° to 40°, as shown in FIG. 4.

A Hall effect sensor is a non-limiting example of a magnetometer. A magnetometer can be used to achieve embodiments within the scope disclosed herein. A Hall effect sensor is a type of magnetometer. However, other magnetometers can be used to sense the drive shaft position. Additionally, a magnetoresistor or magnetoresistive sensor can be used to sense the drive shaft position. Broadly, a sensor that can sense a change in the magnetic field, flux or orientation and has an output that serves as a basis for operation decision can be used to sense the drive shaft position. Additionally, any sensor that senses a change in characteristic of a sensor target can also be used to sense the drive shaft position.

There is no restriction as to the type of Hall effect sensor that can be used. Herein, “Hall effect sensor” and “sensor” are used synonymously and interchangeably when referring to a magnetoresistive sensor. Hall effect sensors that can be used include for non-limiting example: a bipolar Hall effect sensor, a linear Hall effect sensor, a discrete Hall effect sensor, a magnetoresistive Hall effect sensor. Hall effect sensors that have built-in amplifiers can be used. Hall effect sensors that do not have built-in amplifiers can also be used.

Magnets and sensors could be incorporated into the tool at a variety of locations that allow movement of one or more magnets relative to the Hall effect sensor. This disclosure is not limited in regard to a means to place or fix one or more magnets for sensing by the Hall effect sensor. A magnet can be affixed to a member of the tool and/or the tool potting. In an embodiment, plastic can be molded over the magnet.

The magnets can be configured at various distances and in a number of configurations in relation to the Hall effect sensor. One magnet, or a number of magnets can be used to provide input to the Hall effect sensor. Magnets of different strengths and different polarities can be used.

In an embodiment, one or more N35 and/or N35SH magnets can be used. Magnets different from these can be used (e.g. Neodymium Iron Boron magnets). Also, magnetic sources that are not magnets can be used, e.g. magnetized plastics, or magnetically infused plastics (e.g. slider having magnetized portions, magnetized elements, magnetized components, or magnetized plastic portions).

In an alternate embodiment, instead of the magnet moving relative to the sensor, the sensor can move relative to the magnet. In such an embodiment, the Hall effect sensor can be disposed on the drive shaft and the magnet can be in a fixed position on a mounting frame or other portion of the housing 12. In this embodiment, the Hall effect sensor can move with respect to the magnet in order to sense the relative magnetic orientation or relative magnetic flux.

Although the illustrated magazine assembly 14 is configured to receive fasteners that collated in a stick configuration, it is also contemplated that a magazine assembly that is configured to accommodate fasteners that are collated in a coil formation may also be used. The illustrated embodiment is not intended to be limiting in any way.

While aspects of the present invention are described herein and illustrated in the accompanying drawings in the context of a fastening tool, those of ordinary skill in the art will appreciate that the invention, in its broadest aspects, has further applicability.

It will be appreciated that the above description is merely exemplary in nature and is not intended to limit the present disclosure, its application or uses. While specific examples have been described in the specification and illustrated in the drawings, it will be understood by those of ordinary skill in the art that various changes may be made and equivalents may be substituted for elements thereof without departing from the scope of the present disclosure as defined in the claims. Furthermore, the mixing and matching of features, elements and/or functions between various examples is expressly contemplated herein, even if not specifically shown or described, so that one of ordinary skill in the art would appreciate from this disclosure that features, elements and/or functions of one example may be incorporated into another example as appropriate, unless described otherwise, above. Moreover, many modifications may be made to adapt a particular situation or material to the teachings of the present disclosure without departing from the essential scope thereof. Therefore, it is intended that the present disclosure not be limited to the particular examples illustrated by the drawings and described in the specification as the best mode presently contemplated for carrying out the teachings of the present disclosure, but that the scope of the present disclosure will include any embodiments falling within the foregoing description and the appended claims.

What is claimed is:

1. A fastening tool comprising:
a housing;
a nosepiece assembly connected to the housing and including a fastener drive track having a drive axis;
a magazine assembly for feeding a number of fasteners successively along a fastener channel to the fastener drive track of the nosepiece assembly;
a driver member provided in the housing and configured for movement along the drive axis to drive a lead fastener into a workpiece;
a motor disposed within the housing and configured to drive the driver member along the drive axis;
a power source providing power to the motor;
a controller in the tool housing configured to control a supply of power from the power source to the motor and initiate a drive cycle;
a drive assembly having a drive shaft rotatably connected to the driver member;
a sensor target disposed on one end of the drive shaft and having a characteristic that changes in response to the change in position; and
a sensor configured to sense the characteristic of the sensor target and send a signal to the controller in response to the characteristic,
wherein when the controller receives the signal from the sensor, the controller starts the next drive cycle.

2. The fastening tool of claim 1, wherein the switch operation includes changing a signal between ON and OFF

3. The fastening tool of claim 1, wherein the tool housing includes a trigger assembly that activates a driver cycle that causes the compressor piston to travel between at least two positions, and
wherein the controller in the tool housing connects the trigger assembly to the drive assembly.

4. The fastening tool of claim 3, wherein the housing defines a handle portion, and wherein the trigger assembly is connected to the tool housing, adjacent the handle portion.

5. The fastening tool of claim 1, wherein the sensor target is a magnet.

6. The fastening tool of claim 1, wherein the sensor is a Hall effect sensor.

7. The fastening tool of claim 1, wherein the sensor is an omnipolar switch Hall effect sensor.

8. The fastening tool of claim 1, wherein the sensor target is mounted on one of the drive shaft and the housing.

9. The fastening tool of claim 8, wherein the sensor target is mounted on the other of the drive shaft and the housing.

10. The fastening tool of claim 1, further comprising a compression piston disposed within a first compression chamber in the housing; and
an eccentric member rotatable by the drive shaft and slidably connected to the compression piston,
wherein the eccentric member controls a position of a compression piston member within the first compression chamber.
